(19) United States
(12) Patent Application Publication
(10) Pub. No.: US 2023/0417844 A1
(43) Pub. Date: Dec. 28, 2023

(54) DISCONNECTION DETECTION DEVICE AND CONTROL DEVICE

(71) Applicant: ISUZU MOTORS LIMITED, Yokohama-shi (JP)

(72) Inventors: Mitsuyuki AKATA, Fujisawa-shi (JP); Yuta ICHINOSE, Fujisawa-shi (JP)

(21) Appl. No.: 18/278,426

(22) PCT Filed: Feb. 24, 2022
(86) PCT No.: PCT/JP2022/007651

§ 371 Date: Aug. 23, 2023

(30) Foreign Application Priority Data
Feb. 25, 2021 (JP) 2021-028701
Feb. 25, 2021 (JP) 2021028701

(51) Int. Cl. G01R 31/54

(52) U.S. Cl. CPC G01R 31/54

(57) ABSTRACT

This disconnection detection device and control device can increase disconnection detection accuracy. The disconnection detection device includes: a control unit that has an input terminal and a ground connection terminal; a switch having opposite terminals, one of which is connected to the input terminal through wiring and the other of which is connected to the ground through wiring; and a resistor connected in parallel to the switch. The switch and the resistor are connected to each other by crimping.

### TECHNICAL FIELD

The present disclosure relates to a disconnection detection apparatus and a control apparatus.

### BACKGROUND ART

Conventionally, a disconnection detection apparatus is configured, for example, to divide a voltage on the ground side of an abnormal temperature switch by a plurality of resistors to directly input the voltage to an input port of a microcomputer in a circuit in which the abnormal temperature switch is inserted in series in a power supply line (see, for example, Patent Literature (hereinafter, referred to as “PTL”)1). This makes it possible to detect the presence or absence of a circuit abnormality in a voltage dividing circuit.

A signal line extending from each of opposite terminals of each of the resistors is connected to the ground side. For example, as illustrated in FIG. 1, the signal line is connected to the ground side by joint connector 1.

### CITATION LIST

### Patent Literature

### PTL 1

### Japanese Patent Application Laid-Open No. 2014-106219

### SUMMARY OF INVENTION

### Technical Problem

Meanwhile, when the signal line is broken between joint connectors 1, energization is possible through resistor 2. Thus, there are sections 3 in which disconnection cannot be detected. As a result, there is a problem of lowered disconnection detection accuracy.

An object of the present disclosure is to provide a disconnection detection apparatus and a control apparatus capable of increasing disconnection detection accuracy.

### Solution to Problem

In order to achieve the above object, a disconnection detection apparatus in the present disclosure is a disconnection detection apparatus including:

a control unit including an input terminal and a ground connection terminal;

a switch including opposite terminals, one of the opposite terminals being connected to the input terminal via a wire, an other of the opposite terminals being connected to a ground via the wire; and

a resistor connected in parallel with the switch, in which

the switch and the resistor are connected to each other by crimping.

A control apparatus includes a control section that executes a control for causing a display section to display a detection result of the disconnection detection apparatus.

### ADVANTAGEOUS EFFECTS OF INVENTION

According to the present disclosure, it is possible to improve disconnection detection accuracy.

### BRIEF DESCRIPTION OF DRAWINGS

FIG. 1 is a diagram illustrating an example of a conventional disconnection detection apparatus;

FIG. 2 illustrates a disconnection detection apparatus according to an embodiment of the present disclosure; and

FIG. 3 is a diagram illustrating an example of the disconnection detection apparatus in which a disconnection position is depicted.

### DESCRIPTION OF EMBODIMENTS

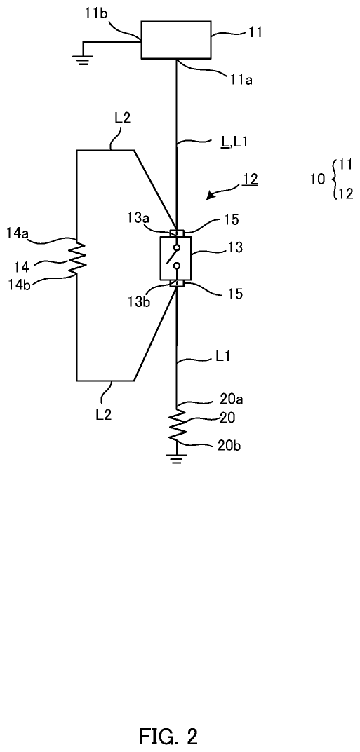

Hereinafter, an embodiment of the present disclosure will be described with reference to the drawings. FIG. 2 is a diagram illustrating an example of disconnection detection apparatus 10 according to the embodiment of the present disclosure. As illustrated in FIG. 2, disconnection detection apparatus 10 includes control unit 11 and detection section 12. Control unit 11 includes a Central Processing Unit (CPU) (not illustrated) and a drive circuit (not illustrated), and detects disconnection of wire L based on a power supply command and a potential of wire L. Here, wire L refers to wire L1 for power supply and wire L2 for resister connection.

The CPU monitors a voltage value obtained through detection section 12 for detecting disconnection of wire L.

The drive circuit supplies power to resistor 20 via wire L1. Here, resistor 20 is a resistor included in a device operating according to switch 13.

Control unit 11 includes input terminal 11a and ground connection terminal 11b. Input terminal 11a is connected to one terminal 20a of resistor 20 via wire L1 and detection section 12. Other terminal 20b of resistor 20 is connected to the ground. Ground connection terminal 11b is connected to the ground.

Detection section 12 includes switch 13 and resistor 14. Switch 13 and resistor 14 are connected in parallel. In the following description, a circuit in which switch 13 and resistor 14 are connected in parallel is referred to as a “parallel circuit.”

Switch 13 is, for example, a switch that is turned ON/OFF by an operator (user). One terminal 13a of switch 13 is connected to the other end of wire L1.

Other terminal 13b of switch 13 is connected to one terminal 20a of resistor 20 via wire L1.

In the parallel circuit, one terminal 13a of switch 13 and wire L2 extending from one terminal 14a of resistor 14 are connected to each other. Other terminal 13b of the switch and wire L2 extending from other terminal 14b of resistor 14 are connected to each other. In the following description, each of a portion where one terminal 13a and wire L2 are connected to each other and a portion where other terminal 13b and wire L2 are connected to each other is referred to as a “branch portion.”

Double crimping is used at branch portions 15. Specifically, at branch portions one terminal 13a of switch 13 and wire L2 are connected to each other by double crimping. Other terminal 13b of switch 13 and wire L2 are connected to each other by double crimping. Since the double crimping is performed by a known method, a description thereof is omitted.

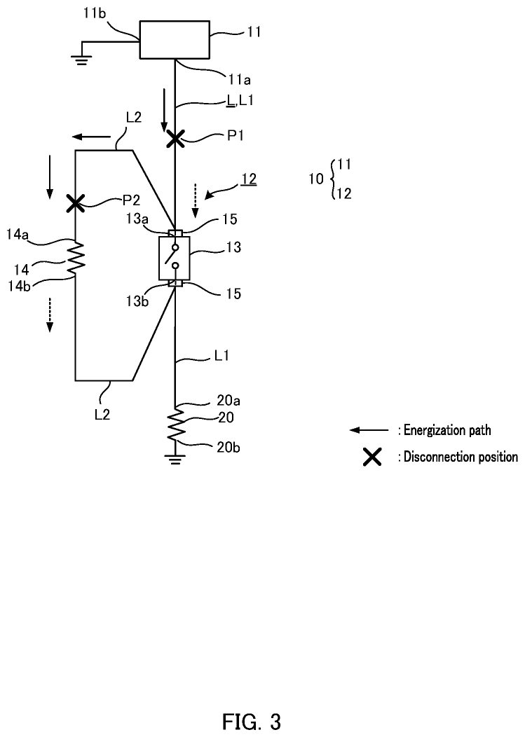

An example of a disconnection detection method will be described with reference to FIG. 3. FIG. 3 is a diagram illustrating an example of disconnection detection apparatus in which a disconnection position is depicted. In FIG. 3, the disconnection position is indicated by “x.”

### (Normal State)

When none of wires L (L1 and L2) are disconnected (normal state), the current is divided between the switch 13 side and the resistor 14 side when switch 13 is turned ON. Accordingly, voltage value V obtained through detection section 12 is voltage value Va applied to the internal resistance on the switch 13 side. Letting the resistance value of the internal resistance be “Ra” and the current value of the current diverted to the internal resistance side be “Ia,” voltage value Va=Ia*Ra. Therefore, the CPU sets normal voltage value Va (=Ia*Ra) as a normal value and monitors disconnection of wires L based on normal value Va.

### (Disconnected State)

When wire L1 is disconnected at position P1, no current flows through detection section 12 even when switch 13 is turned ON. As a result, voltage value V obtained through detection section 12 is “0.” Therefore, the CPU detects the disconnection of wires L because voltage value V obtained through detection section 12 is “0” and differs from normal value Va.

When wire L2 is disconnected at position P2, current flows only to the switch 13 side when switch 13 is turned ON. Accordingly, voltage value V obtained through detection section 12 is voltage value Vb applied to the internal resistance on the switch 13 side. Letting the current value flowing only to the internal resistance be “Ib,” voltage value Vb=Ib*Ra. Therefore, the CPU detects the disconnection of wires L because voltage value V obtained through detection section 12 is “Vb” and differs from normal value Va.

As described above, the CPU is capable of detecting the disconnection of wires L (L1, L2) from difference of voltage value V obtained through detection section 12 from normal value Va.

A control apparatus (not illustrated) includes a control section (not illustrated) that executes control for causing a display apparatus (not illustrated), for example, to display a disconnection detection result of the disconnection detection by the CPU. Since the disconnection detection result is displayed on the display apparatus, the operator (user) can visually recognize the presence or absence of the disconnection.

Disconnection detection apparatus 10 according to the above embodiment includes control unit 11 including input terminal lla and ground connection terminal 11b, and switch 13 including opposite terminals, one of the opposite terminals being connected to input terminal 11a via wire L, the other of the terminals being connected to the ground via wire L1, and resistor 14 connected in parallel with switch 13, in which one terminal 13a of switch 13 and wire L2 extending from one terminal 14a of resistor 14 are connected to each other by double crimping. Further, other terminal 13b of switch 13 and wire L2 extending from other terminal 14b of resistor 14 are connected to each other by double crimping.

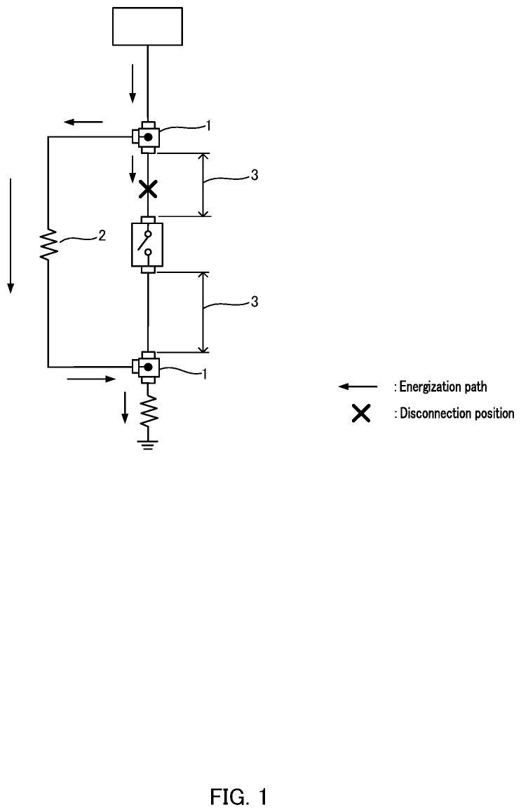

With the above-described configuration, by adopting the double crimping without using a joint connector at branch portions 15 which are the portion where one terminal 13a and wire L2 are connected to each other and the portion where other terminal 13b and wire L2 are connected to each other, it is possible to eliminate a section in which disconnection cannot be detected (for example, sections 3 illustrated in FIG. 1 or the like). Accordingly, even when wire L1 or L2 is disconnected at any position, the disconnection is detected. Thus, the disconnection detection accuracy can be increased.

In the above-described embodiment, disconnection detection apparatus 10 is applied to the disconnection of the power supply wire, but may be applied to disconnection of a signal wire.

Each of the above-described embodiment merely shows an example of specific implementation of the present disclosure, and the technical scope of the present disclosure should not be construed to be limited thereto. That is, the present disclosure can be implemented in various forms without departing from its spirit or key features.

This application is entitled to and claims the benefit of Japanese Patent Application No. 2021-028701 filed on Feb. 25, 2021, the disclosure of which including the specification, drawings and abstract is incorporated herein by reference in its entirety.

### INDUSTRIAL APPLICABILITY

The present disclosure is suitably applied to a control apparatus that is required to increase disconnection detection accuracy.

### REFERENCE SIGNS LIST

1 Joint connector
2 Resistor
3 Section
10 Disconnection detection apparatus
11 Control unit
12 Detection section
13 Switch
13a One terminal
13b Other terminal
14 Resistor
14a One terminal
14b Other terminal
15 Branch portion
20 Resistor
20a One terminal
20b Other terminal

1. A disconnection detection apparatus, comprising:
a control unit including an input terminal and a ground connection terminal;
a switch including opposite terminals, one of the opposite terminals being connected to the input terminal via a wire, an other of the opposite terminals being connected to a ground via the wire; and
a resistor connected in parallel with the switch, wherein
the switch and the resistor are connected to each other by crimping.

2. A control apparatus, comprising:
a control section that executes control for causing a display section to display a detection result of disconnection detection by a disconnection detection apparatus according to claim 1.
